(19) United States
(12) Patent Application Publication
(10) Pub. No.: US 2008/0239859 A1
(43) Pub. Date: Oct. 2, 2008

(54) ACCESS DEVICE

(75) Inventors: Georg Georgakos, Erding (DE); Jorg Berthold, Munchen (DE); Florian Bauer, Munchen (DE); Christian Pacha, Munchen (DE)

Correspondence Address: SCHWEGMAN, LUNDBERG & WOESSNER / INFINEON, P.O. BOX 2938, MINNEAPOLIS, MN, 55402, US

(73) Assignee: INFINEON TECHNOLOGIES AG, MUNICH (DE)

(21) Appl. No.: 11/693,910

(22) Filed: Mar. 30, 2007

(51) Int. Cl. G11C 5/14; H01L 29/786

(52) U.S. Cl. 365/229; 257/347; 257/E29.273

(57) ABSTRACT

P-type multi gate field effect transistor access devices are adapted to be coupled to a memory cell to provide access to the memory cell. A method is described that uses a power switch to switch off address decoding circuitry allowing word lines to float toward a high supply voltage, turning off the p-type multi gate field effect transistor access devices.

### BACKGROUND

Recent CMOS (complementary metal oxide semiconductor) technologies use circuit techniques to comply with specification for power dissipation in active and standby modes. Standby power may be mainly a function of leakage current of transistors, which increases by factors of up to ten in sub-100 nm technologies compared to older generations. One of the most effective circuit techniques to cope with the increased leakage is a combination of power switching and voltage scaling, achieving leakage reduction ratios of more than 10.

Static random access memory (SRAM) may be a large contributor to power consumption in standby modes of devices. In some devices, SRAM cell arrays may receive a lower voltage to reduce leakage during standby. This is referred to as voltage scaling. Periphery circuits, such as wordline drivers and address decoders may be switched off. This is referred to as power switching.

SRAM arrays are normally implemented with n-FET (n-type field effect transistor) based access devices. N-FET access devices have generally high current driving abilities as compared to p-type FETs (p-FET), and are generally more stable with time. With this SRAM implementation, periphery circuits are switched off using p-FET switch transistors. This ensures that word lines coupling the periphery circuits to the SRAM arrays drift toward ground, ensuring that the n-FET access devices in the SRAM arrays are off or closed during standby, and that the SRAM array correctly maintains stored data.

In recent CMOS technologies, p-FETs are often subjected to additional leakage mechanisms, which results in higher leakage currents of p-FET switches. Additionally, such p-FET switches may utilize multiple wells to reduce leakage, but require additional chip real estate. Still further, device stability of p-FET switches may be less stable than other switches.

### BRIEF DESCRIPTION OF THE DRAWINGS

FIG. 1 is a circuit diagram of a static random access memory having p-type multi gate field effect access transistors according to an example embodiment.

FIG. 2 is a block perspective diagram of an example p-type multi gate field effect transistor access device for use in the static random access memory of FIG. 1.

FIG. 3 is an example layout of the circuit of FIG. 1.

FIG. 4 is a block circuit diagram illustrating multi gate field effect transistor power switches and periphery circuitry for a static random access memory array according to an example embodiment.

### DETAILED DESCRIPTION

In the following description, reference is made to the accompanying drawings that form a part hereof, and in which is shown by way of illustration specific embodiments which may be practiced. These embodiments are described in sufficient detail to enable those skilled in the art to practice the invention, and it is to be understood that other embodiments may be utilized and that structural, logical and electrical changes may be made without departing from the scope of the present invention. The following description of example embodiments is, therefore, not to be taken in a limited sense, and the scope of the present invention is defined by the appended claims.

A static random access memory (SRAM) is implemented with p-type multi gate field effect transistor (MuGFET) access devices. P-MuGFET (p-type MuGFET) devices are in an off mode when their gates are driven to a high voltage, and are on when their gates are driven to a low voltage. In one embodiment, periphery access circuitry, such as word line decoders are switched off by use of n-MuGFET (n-type MuGFET) power switches that are disposed between ground or VSS and the access circuitry. When the power switches are off, as controlled by application of a low voltage, the access circuitry floats toward the supply voltage or VDD, ensuring that the word lines also move toward a high voltage, which in turn ensures that the p-MuGFET access devices are off, further reducing leakage current.

FIG. 1 is a circuit diagram of a six transistor SRAM cell 100. A pair of p-type MuGFET access transistors 110 and 112 have gates adapted to be coupled to a word line 115, and sources adapted to be respectively coupled to a bit line (BL) 117 and complementary bit line (BLB) 118. A pair of p-type MuGFET pull up transistors 120 and 122 and a pair of n-type MuGFET pull down transistors 130 and 132 are coupled to form cross coupled inverters indicated by broken line 135. The pull up transistors 120 and 122 are coupled to a supply voltage 140 (VDD) and the pull down transistors 130, 132 are coupled to ground 145 (VSS).

The phase “adapted to be coupled” may be taken to correspond to the layout or sizing of devices to allow coupling, or performance of functions, or other aspects of devices so coupled.

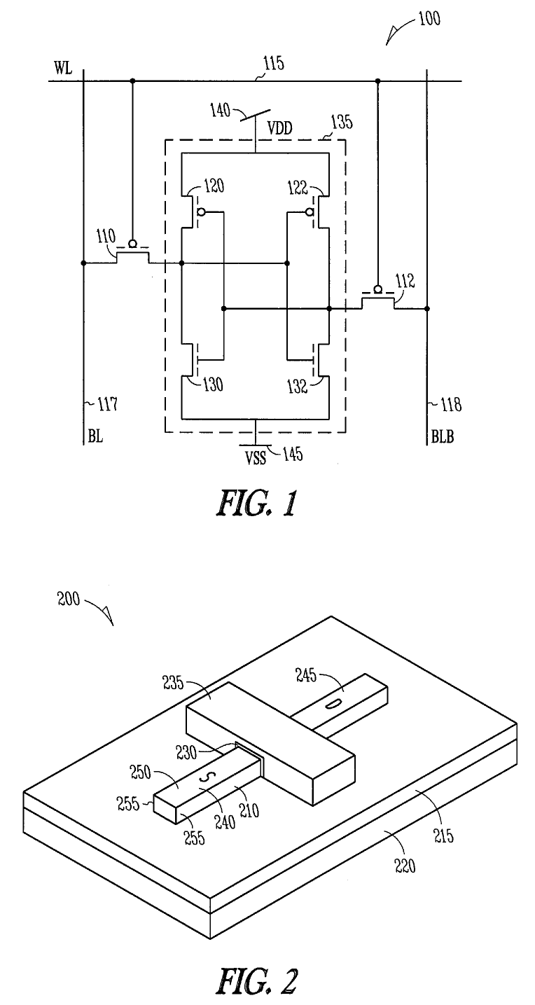

FIG. 2 is a block perspective diagram of an example p-type multi gate field effect transistor access device 200 for use in the static random access memory of FIG. 1. Transistor 200 may be a single p-type fin transistor 200 and has a body 210, also referred to as a fin 210. The fin may be formed on an insulating surface 215 of a substrate 220. The insulating surface may be a buried oxide or other insulating layer 215 over a silicon or other semiconductor substrate 220. A gate dielectric 230 is formed over the top and on the sides of the semiconductor fin 210. A gate electrode 235 is formed over the top and on the sides of the gate dielectric 230 and may include a metal layer. Source 240 and drain 245 regions may be formed in the semiconductor fin 210 on either side of the gate electrode, and may be laterally expanded to be significantly larger than the fin 210 under the gate electrode 235 in various embodiments.

The fin 210 has a top surface 250 and laterally opposite sidewalls 255. The semiconductor fin has a height or thickness equal to T and a width equal to W. The gate width of a single fin MuGFET transistor is equal to the sum of the gate widths of each of the three gates formed on the semiconductor body, or, T+W+T, which provides high gain. Better noise immunity may result from forming the transistors on an insulator. Formation on the insulator provides isolation between devices, and hence the better noise immunity. It further alleviates the need for multiple large well areas to reduce leakage currents, further leading to reduced real estate needs. Having the gate traverse two or more sides of the fin or channel results in much quicker off current than prior bulk CMOS devices. Further, the current characteristics of p-type MuGFET devices may exhibit similar or higher gain than corresponding n-type MuGFET devices. This may reduce the potential effects of degradation of devices over time.

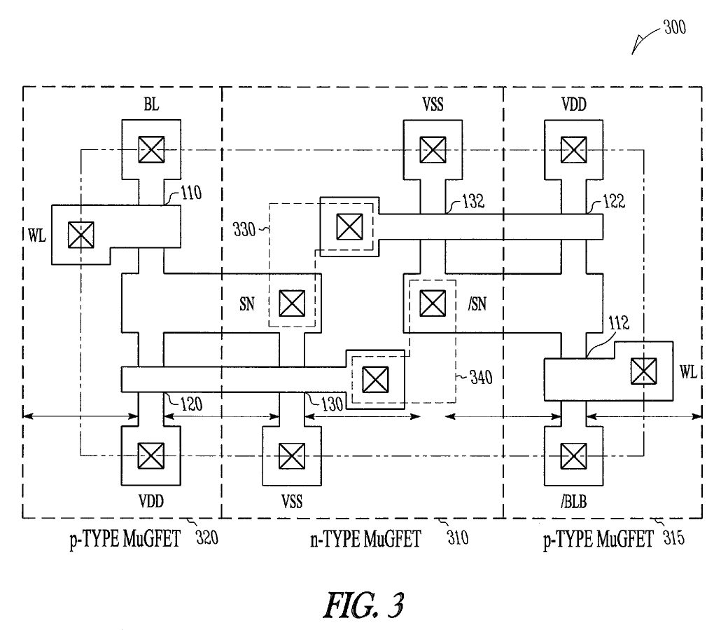

The use of MuGFET transistors may also provide a better subthreshold slope that is steeper than bulk CMOS devices, so a device switches off more quickly. Since the channels are formed by the use of undoped narrow fins that may be formed with substantially similar dimensions using well controlled processes, device mismatch due to dopant fluctuation is not a concern. Therefore, improved matching of the devices may be easier than in bulk CMOS devices. FIG. 3 is an example layout 300 of the circuit of FIG. 1. While several different layouts may be used, layout 300 provides for grouping of different doped devices into separate areas which facilitates folding out the layout to produce an array of memory cells. n-MuGFET devices are contained in an area defined by broken line 310, and p-MuGFET devices are contained in two areas 315 and 320 on either side of area 310. Fold out of the layout 300 in one embodiment results in shared VDD for adjacent cells, and columns of n-type and p-type areas.

In layout 300, devices are identified with reference numbers pointing to their channels, with numbers consistent with those used in FIG. 1. Contacts are identified by an “x”, and are coupled to the various word lines, bit lines, VSS and VDD. Further, in one embodiment, metal conductors 330, 340 are formed between contacts to provide cross coupling of the inventers.

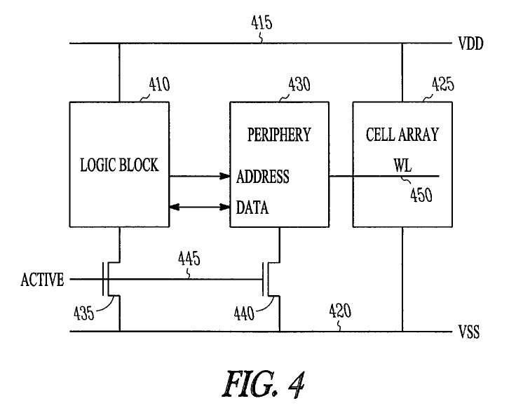

FIG. 4 is a block circuit diagram illustrating multi gate field effect transistor power switches and periphery circuitry for a static random access memory array according to an example embodiment. A logic block 410 is coupled to VDD 415 and VSS 420. Logic block 410 may be any type of device such as a microprocessor, that would like to access a SRAM memory cell array 425 via a periphery circuitry 430. In one embodiment, VDD 415 and/or VSS 420 may be virtual VDD and virtual VSS coupled respectively to a global supply and ground. Memory cell array 425 and periphery circuitry 430 are similarly coupled to VDD 415 and VSS 420. Logic block 410 may be coupled to VSS 420 through a first n-MuGFET power switch 435 in one embodiment. Similarly, periphery circuitry 430 may be coupled through a second n-MuGFET power switch 440 to VSS 420 in a further embodiment.

When the power switch gates are driven with a high voltage level, they turn on, turning on both logic block 410 and periphery circuitry 430. When a power saving mode is entered, the power switches 435 and 440 are turned off by application of a low gate voltage on line 445. This causes voltages within the cell array 425, in particular word lines represented at 450 to float toward VDD and be at a high voltage level approaching or equal to VDD.

Cell array 425 in one embodiment, comprises an array of memory cells 100 having p-MuGFET access devices. As described above, the p-MuGFET access devices are placed in an off condition with low leakage current by word lines that are high. Thus, the total leakage currents in the SRAM cell array 425 may be reduced. The use of n-MuGFET power switches, such as switch 440 further reduces leakage currents, as the switch itself is formed on an insulated substrate in a manner similar to that of access device 200 in FIG. 2.

In one embodiment, it may be desirable to place circuitry into a standby mode to conserve power. The term “standby mode” is meant to cover any mode of operating at a reduced power, and commonly includes but is not limited to standby or sleep mode for computer systems or other devices.

In one embodiment, upon entering a standby mode of low power consumption, circuitry, such as logic 410 and address decoding circuitry 430 are switched off via the power switches 435, 440 being turned off. The circuitry then floats toward a high supply voltage, VDD. Word lines 450 from the memory address decoding circuitry float toward VDD. This results in turning off p-type multi gate field effect transistor access devices in an array 425 of static random access memory cells coupled to the word lines such that leakage currents are reduced. The circuitry is turned off by applying a low voltage to the n-type multi gate field effect transistor power switches 435, 440

The Abstract is provided to comply with 37 C.F.R. §1.72(b) to allow the reader to quickly ascertain the nature and gist of the technical disclosure. The Abstract is submitted with the understanding that it will not be used to interpret or limit the scope or meaning of the claims.

1. A device comprising:
p-type multi gate field effect transistor access devices adapted to be coupled to a memory cell.

2. The device of claim 1 wherein the p-type multi gate field effect access devices each comprise a p-type single fin.

3. The device of claim 2 wherein the single fins are supported by an insulated substrate and have a gate dielectric separating a gate electrode formed over a portion of the fins.

4. The device of claim 3 wherein the substrate is insulated with a buried oxide layer.

5. The device of claim 4 wherein the memory cell is a static random access memory cell having cross coupled inverters.

6. The device of claim 5 wherein the gate electrode is adapted to be coupled to a word line that is held high during a standby mode to reduce leakage currents.

7. The device of claim 2 wherein the single fins are supported by an electrical insulation layer and have a gate dielectric separating a gate electrode formed over a portion of the fins.

8. A static random access memory cell comprising:
a pair of p-type multi gate field effect transistor access devices coupled to bit lines and having gates adapted to be coupled to a word line;
a pair of p-type multi gate field effect transistor pull-up devices, each having a gate coupled to a respective drain of the p-type multi gate field effect transistor access devices and adapted to be coupled to a supply voltage;
a pair of n-type multi gate field effect transistor pull-down devices, each having a gate coupled to a respective one of the p-type multi gate field effect transistor access devices and adapted to be coupled to a ground, wherein the pull-up and pull-down devices form a cross coupled inverter.

9. The memory cell of claim 8 wherein the p-type multi gate field effect access devices each comprise a p-type single fin.

10. The memory cell of claim 9 wherein the single fins are supported by an insulated substrate and have a gate dielectric separating a gate electrode formed over a portion of the single fin.

11. The memory cell of claim 10 wherein the substrate is insulated with a buried oxide layer.

12. The memory cell of claim 11 wherein the gate electrode is coupled to a word line that is held high during a standby mode to reduce leakage currents.

13. The memory cell of claim 10 wherein the single fins are supported by an electrical insulation layer and have a gate dielectric separating a gate electrode formed over a portion of the fins.

14. A static random access memory comprising:
an array of memory cells having cross coupled inverters with p-type multi gate field effect transistor access devices;
word lines coupled to the p-type multi gate field effect transistor access devices;
decoding circuitry coupled to the word lines; and
a power switch coupled between a ground and the decoding circuitry.

15. The memory of claim 14 wherein the ground comprises a virtual ground.

16. The memory of claim 14 wherein the power switch comprises an n-type multi gate field effect transistor power switch.

17. The memory of claim 16 wherein a low voltage applied to a gate of the power switch turns off the power switch and the decoding circuitry, which floats toward a supply voltage, turning off p-type multi gate field effect transistor access devices that are coupled to associated word lines.

18. The memory of claim 14 and further comprising a logic block coupled to the decoding circuitry and a power switch coupled between the logic block and ground.

19. The memory of claim 18 wherein both power switches have gates coupled to a single control signal.

20. A static random access memory comprising:
an array of memory cells comprising:
a pair of p-type multi gate field effect transistor access devices coupled to bit lines and having gates;
a pair of p-type multi gate field effect transistor pull-up devices, each having a gate coupled to a respective drain of the p-type multi gate field effect transistor access devices and adapted to be coupled to a supply voltage; and
a pair of n-type multi gate field effect transistor pull-down devices, each having a gate coupled to a respective one of the p-type multi gate field effect transistor access devices and adapted to be coupled to a ground, wherein the pull-up and pull-down devices form a cross coupled inverter having cross coupled inverters with p-type multi gate field effect transistor access devices;
word lines coupled to the p-type multi gate field effect transistor access devices;
decoding circuitry coupled to the word lines; and
a power switch coupled between a ground and the decoding circuitry.

21. The memory of claim 20 wherein the ground comprises a virtual ground.

22. The memory of claim 20 wherein the power switch comprises an n-type multi gate field effect transistor power switch.

23. The memory of claim 22 wherein a low voltage applied to a gate of the power switch turns off the power switch and the decoding circuitry, which floats toward a supply voltage, turning off p-type multi gate field effect transistor access devices that are coupled to associated word lines.

24. The memory of claim 20 and further comprising a logic block coupled to the decoding circuitry and a power switch coupled between the logic block and ground.

25. The memory of claim 24 wherein both power switches have gates coupled to a single control signal.

26. A method comprising:
entering a standby mode of low power consumption;
switching off memory address decoding circuitry in response to entering the standby mode, such that it floats toward a high supply voltage;
allowing word lines from the memory address decoding circuitry to float toward the high supply voltage; and
turning off p-type multi gate field effect transistor access devices in an array of static random access memory cells coupled to the word lines such that leakage currents are reduced.

27. The method of claim 26 wherein switching off memory address decoding circuitry is performed by applying a low voltage to an n-type multi gate field effect transistor that is coupled to ground.

28. The method of claim 26 and further comprising switching off logic circuitry in response to entering the standby mode.

29. A memory device comprising:
means for switching off memory address decoding circuitry in response to entering a standby mode, such that it floats toward a high supply voltage;
means for allowing word lines from the memory address decoding circuitry to float toward the high supply voltage; and
means for turning off p-type multi gate field effect transistor access devices in an array of static random access memory cells coupled to the word lines such that leakage currents are reduced.
